(19) United States
(12) Patent Application Publication
(10) Pub. No.: US 2014/0319612 A1
(43) Pub. Date: Oct. 30, 2014

(54) SEMICONDUCTOR-ON-INSULATOR STRUCTURE AND PROCESS FOR PRODUCING SAME

(71) Applicant: The Silanna Group Pty Ltd, Eight Mile Plains, Queensland (AU)

(72) Inventor: Andrew John Brawley, Cecil Hills (AU)

(21) Appl. No.: 14/356,880

(22) PCT Filed: Nov. 2, 2012
(86) PCT No.: PCT/AU2012/001347

§ 371 Date: May 7, 2014

Related U.S. Application Data
(60) Provisional application No. 61/556,772, filed on Nov. 7, 2011.

(51) Int. Cl. H01L 29/786; H01L 27/12; H01L 21/84; H01L 29/66

(52) U.S. Cl. CPC H01L 29/78603; H01L 29/66742; H01L 27/1203; H01L 21/84
USPC 257/351; 438/153

(57) ABSTRACT

A semiconductor-on-insulator structure, including a semiconductor thin film having electronic devices formed therein, the semiconductor thin film being disposed on a first face of an electrically insulating thin film; wherein to reduce parasitic capacitance, there is no bulk substrate attached to a second face of the electrically insulating thin film opposite to the first face, and to provide a path for heat flow from the devices, the thermal conductivity of the electrically insulating thin film is substantially greater than 1.4 W·m⁻¹·K⁻¹.

### TECHNICAL FIELD

The present invention relates to semiconductor processing, and in particular to a semiconductor-on-insulator structure and a process for producing a semiconductor-on-insulator structure.

### BACKGROUND

Although current processes for forming integrated circuits and semiconductor devices are exceedingly complex, the fundamental steps of such processes involve introducing controlled amounts of impurities into selected regions of a semiconducting material to modify the electrical properties of those regions, and then forming electrical contacts to some of those regions by depositing metals such as aluminium or, more recently, copper, to form conductive pathways. The starting material for these processes is a semiconductor body generically referred to in the art as a ‘substrate’, usually (but not necessarily) in the form of a generally circular thin disc referred to in the art as a ‘wafer’.

Traditionally, integrated circuits and microelectronic devices have been formed in ‘bulk’ semiconductor (e.g., germanium or silicon) wafers composed only of the semiconductor itself (ignoring impurities). Consequently, the thickness of a semiconductor wafer (generally a few millimetres) is typically orders of magnitude greater than the relatively thin surface regions of the wafer in which the devices are formed (generally some micrometers or less). However, in recent decades the performance of state-of-the-art semiconductor devices has been improved by forming them in a type of substrate referred to in the art as silicon-on-insulator, or more generally, semiconductor-on-insulator (SOI) substrates, in which only a thin layer of the semiconductor is disposed on an electrical insulator. SOI substrates are produced in one of two forms: (i) as a thin semiconductor layer on a thick, self-supporting bulk insulator such as a wafer of sapphire or glass, or (ii) as a thin semiconductor layer on a thin electrically insulating layer such as silicon dioxide on a thick, self-supporting bulk semiconductor wafer.

Semiconductor devices formed in semiconductor-on-insulator (SOI) substrates have improved performance relative to their counterparts formed in bulk semiconductor substrates due to reduced parasitic capacitance, greater resistance to latch-up, and the ability to create fully depleted and/or partially depleted transistors. However, due to the presence of the insulator (whether in thin film or bulk form), SOI substrates have poorer thermal conductance than bulk semiconductor substrates, and consequently thermal management to reduce self-heating is becoming an ever increasing problem as device densities and frequencies continue to increase. In any case, the continuing demands of the marketplace mean there is a continual need for greater performance and lower cost.

It is desired to provide a semiconductor-on-insulator structure and a process for producing a semiconductor-on-insulator structure that alleviate one or more difficulties of the prior art, or that at least provide a useful alternative.

### SUMMARY

In accordance with some embodiments of the present invention, there is provided a semiconductor-on-insulator structure, including a semiconductor thin film having electronic devices formed therein, the semiconductor thin film being disposed on a first face of an electrically insulating thin film; wherein to reduce parasitic capacitance, there is no bulk substrate attached to a second face of the electrically insulating thin film opposite to the first face, and to provide a path for heat flow from the devices, the thermal conductivity of the electrically insulating thin film is substantially greater than 1.4 W·m⁻¹·K⁻¹.

In some embodiments, there is no other layer with a thermal conductivity comparable to that of the electrically insulating thin film attached to the second face of the electrically insulating thin film. This means there is no such layer attached below the electrically insulating thin film when oriented in the usual manner as illustrated in FIGS. 1 and 2, but does not preclude one or more such layers above the semiconductor thin film.

In some embodiments, there is substantially no other layer attached to the second face of the electrically insulating thin film.

In some embodiments, the electrically insulating thin film is a crystalline thin film having an epitaxial relationship with the semiconductor thin film.

In some embodiments, the thermal conductivity of the electrically insulating thin film is at least 14 W·m⁻¹·K⁻¹. In some embodiments, the thermal conductivity of the electrically insulating thin film is at least about 100 W·m⁻¹·K⁻¹. In some embodiments, the thermal conductivity of the electrically insulating thin film is at least nearly equal to that of the semiconductor thin film. In some embodiments, the thermal conductivity of the electrically insulating thin film is greater than that of the semiconductor thin film.

In some embodiments, the structure includes at least one interconnect layer disposed on the semiconductor thin film, the at least one interconnect layer including electrical contacts to the devices in the semiconductor thin film.

In some embodiments, the structure includes one or more bond pads extending from the at least one interconnect layer through the semiconductor thin film and the electrically insulating thin film to provide electrical contacts to the devices and to provide a thermal path for heat flow from the devices and the electrically insulating thin film.

In some embodiments, the structure includes a support attached to the interconnect layer to provide mechanical support for the semiconductor thin film and the electrically insulating thin film.

In some embodiments, the devices include fully-depleted and/or partially depleted CMOS devices. In some embodiments, the devices include RF switches.

In some embodiments, the electrically insulating thin film is an AlN thin film. In some embodiments, the semiconductor thin film is a silicon thin film.

In accordance with some embodiments of the present invention, there is provided a process for producing a semiconductor-on-insulator structure, including:
forming a semiconductor thin film disposed on a first face of an electrically insulating thin film;
forming electronic devices in the semiconductor thin film;
wherein to reduce parasitic capacitance, there is no bulk substrate attached to a second face of the electrically insulating thin film opposite to the first face, and to provide a path for heat flow from the devices, the thermal conductivity of the electrically insulating thin film is substantially greater than 1.4 W·m⁻¹·K⁻¹.

In some embodiments, there is no other layer with a thermal conductivity comparable to that of the electrically insulating thin film attached to the second face of the electrically insulating thin film.

In some embodiments, there is substantially no other layer attached to the second face of the electrically insulating thin film.

In some embodiments, the electrically insulating thin film is a crystalline thin film having an epitaxial relationship with the semiconductor thin film.

In some embodiments, the thermal conductivity of the electrically insulating thin film is at least 14 W·m⁻¹·K⁻¹. In some embodiments, the thermal conductivity of the electrically insulating thin film is at least about 100 W·m⁻¹·K⁻¹. In some embodiments, the thermal conductivity of the electrically insulating thin film is at least nearly equal to that of the semiconductor thin film. In some embodiments, the thermal conductivity of the electrically insulating thin film is greater than that of the thin film semiconductor.

Also described herein is a process for producing a semiconductor-on-insulator structure, including:

forming an electrically insulating thin film on a semiconductor substrate, the electrically insulating thin film having a thermal conductivity that is equal to or greater than the thermal conductivity of the semiconductor substrate;

directing an energetic beam of particles into the semiconductor substrate to form a buried implanted layer within the semiconductor substrate;

bonding a first handle layer to the electrically insulating thin film;

splitting the semiconductor substrate along a layer of structural defects corresponding to the buried implanted layer to leave a relatively thin layer of the semiconductor substrate bonded to the electrically insulating thin film;

polishing the relatively thin layer of the semiconductor substrate to provide a semiconductor thin film disposed on the electrically insulating thin film;

forming devices in the thin layer of semiconductor; and

removing the first handle layer from the electrically insulating layer.

### BRIEF DESCRIPTION OF THE DRAWINGS

Some embodiments of the present invention are hereinafter described, by way of example only, with reference to the accompanying drawings, wherein:

FIG. 1 is a schematic cross-sectional side view of a semiconductor-on-insulator structure in accordance with some embodiments of the present invention;

FIG. 2 is a schematic cross-sectional side view of a semiconductor-on-insulator structure with electronic devices formed therein in accordance with some embodiments of the present invention;

FIG. 3 is a flow diagram of a process for producing a semiconductor-on-insulator structure in accordance with some embodiments of the present invention; and

FIGS. 4 to 14 are schematic cross-sectional side-views of a semiconductor wafer during processing in accordance with the steps of the process of FIG. 3.

### DETAILED DESCRIPTION

The inventor has determined that the high-frequency and/or high-power performance of existing semiconductor devices remain limited by self-heating and by the residual parasitic capacitance of the SOI substrate. To address these difficulties, the inventor has developed a new form of semiconductor-on-insulator structure that will now be described.

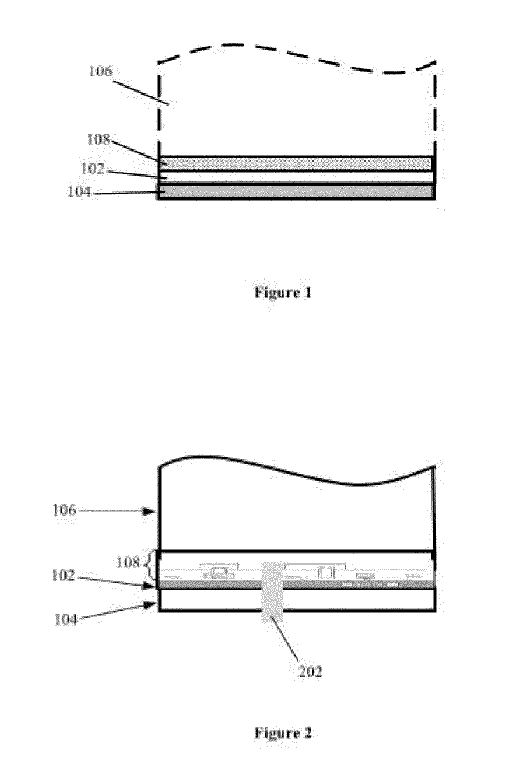

As shown in FIG. 1, a semiconductor-on-insulator structure includes a thin semiconductor film or layer 102 on an electrically insulating but thermally conductive thin film or layer 104. However, unlike prior art SOI structures: (i) there is no bulk substrate attached to the underside of the electrically insulating layer 104 (i.e., the face opposite to the thin semiconductor layer 102), and (ii) the electrically insulating layer 104 is composed of an electrically insulating material selected to have a relatively high thermal conductivity, which in this specification is defined as meaning that its thermal conductivity is substantially greater than that of SiO₂, which is about 1.4 W·m⁻¹·K⁻¹.

The absence of a bulk substrate under the electrically insulating layer 104 further reduces parasitic capacitance relative to prior art SOI structures (including silicon-on-sapphire and similar substrates with bulk insulating substrates), thereby allowing active semiconductor devices in the semiconductor layer 102 to operate at higher frequencies. However, the bulk substrate of a prior art SOI wafer also acts as a heat sink to remove heat generated by the devices in the semiconductor layer 102, and consequently the removal of this heat sink and the desire for high frequency operation mean that self-heating may limit the ability to operate devices in the semiconductor layer at high frequencies. To address this difficulty, the electrically insulating layer 104 is composed of a material selected to have a relatively high thermal conductivity, as described above. In some embodiments, the thermal conductivity of the electrically insulator is at least ten times that of SiO₂; i.e., at least about 14 W·m⁻¹·K⁻¹. In some embodiments, the thermal conductivity of the electrically insulator is at least about 100 W·m⁻¹·K⁻¹. In some embodiments, the thermal conductivity of the electrically insulator is at least nearly equal to that of the thin film semiconductor 102. In some embodiments, the thermal conductivity of the electrically insulator is greater than that of the thin film semiconductor 102.

For example, in embodiments where the semiconductor layer 102 is composed of silicon, the electrically insulating but thermally conductive layer 104 can be composed of Aluminium Nitride (AlN), which has a thermal conductivity that is nearly twice that of silicon. However, the electrically insulating thin film 104 can be composed of any electrically insulating material whose thermal conductivity is substantially greater than that of SiO₂. Typically, the electrically insulating material will be a binary or ternary oxide, nitride, or oxy-nitride of Al, Ga, In, Mg, Zn, Si, Ge, or Gd.

The semiconductor-on-insulator (SOI) structures described herein address the device performance and self-heating difficulties of the prior art by providing substrate-less SOI structures with reduced parasitic capacitance that enable higher frequency performance while also including thin film insulators having higher thermal conductivity than conventional thin film SiO₂ films. As will be appreciated by those skilled in the art, the actual in-plane thermal conductance of the thin film insulator depends not only on its thermal conductivity, but also on its thickness. However, the use of an insulator with relatively high thermal conductivity enhances the thermal conductance of the thin film and hence allows substrate-less SOI structures to be used at higher device frequencies than would otherwise be possible. In practice, the thickness of the thin film insulator can be increased as required to provide sufficient cooling and hence allow the devices in the thin film semiconductor to be operated at a desired operating frequency once the corresponding device power generation density and the configuration and conductivity of any heat sinking structures (including metallic structures such as wire bonds and bumps) are known. Typically, the thickness of the thin film insulator will be in the range from about 50 nm to several microns.

Because the semiconductor layer 102 and the insulating layer 104 are both thin films, they can be fragile when formed in large areas, and consequently will generally require some form of mechanical support in order to prevent cracking or fracture. In the described embodiments, a support in the form of a handle 106 is attached to the upper face of the semiconductor layer 102, as shown by dashed lines in FIG. 1, typically via one or more intermediate interconnect layers 108. However, it will be apparent to those skilled in the art that other forms of support could be used in other embodiments. For example, the thin semiconductor film 102 could be attached to a support only at one or more peripheral regions (e.g., a ring) and/or only at selected locations across the semiconductor thin film 102 (e.g., between devices). It will be apparent to those skilled in the art that a variety of other support configurations are possible.

Although not shown in FIG. 1 for clarity, the semiconductor layer 102 has semiconductor devices formed therein. FIG. 2 shows an SOI structure with active CMOS devices formed in a (100) silicon layer 102 and a handle superstrate 106 in the form of a silicon wafer attached to the semiconductor layer 102 via intermediate device interconnect layers 108. In this schematic representation, a single metal bond pad 202 is also shown projecting through the insulating AlN layer 104, illustrating how signals can be communicated to and from the devices in the silicon layer 102.

The general structures shown in FIGS. 1 and 2 can be produced by a variety of different possible processes. For example, in embodiments where the semiconductor of the device layer 102 is (100) silicon and the composition of the electrically insulating layer 104 is AlN, the AlN layer 104 can be grown or deposited directly onto the silicon layer 102, or alternatively the silicon layer 102 can be grown or deposited directly onto the AlN layer 104, or alternatively both layers 102, 104 can be formed independently and then bonded together.

The silicon layer 102 can be grown or deposited as a thin film, or can be formed by grinding and/or etching back a relatively thick silicon layer or wafer (which could be a bulk wafer or a conventional buried-oxide SOI wafer, for example), or by splitting a thick silicon layer or wafer using a smart Cut™ or ion cut process, followed by chemical-mechanical polishing (CMP).

In some embodiments, a thin AlN layer is grown on a thin Si layer or a bulk silicon substrate, and the AlN layer is then bonded to another AlN layer to increase the thickness (and hence the thermal conductance) of the resulting final AlN layer. In some embodiments, this is achieved by simultaneously growing AlN layers on two silicon substrates, bonding the two AlN layers together, and then thinning one of the Silicon substrates (e.g., by grinding and/or etching, or by an ion cut process followed by chemical-mechanical polishing) and completely removing the other silicon substrate (or alternatively selectively leaving only one or more support portions of the silicon wafer (e.g., in a grid and/or ring pattern) to support the resulting thin films 102, 104). In some embodiments, at least one of the two silicon wafers is an SOI wafer, and the process includes grinding and/or etching the underlying silicon substrate of the SOI wafer to the buried oxide layer and then stripping the oxide layer to leave only the thin (100) silicon device layer. Processes for forming a thin silicon layer on bonded AlN layers are described in U.S. Patent Application No. 61/556,121 filed on Nov. 4, 2011 and in the corresponding International (PCT) Patent Application filed on Nov. 2, 2012, both entitled Method of producing a Silicon-on-Insulator Article, and the entirety of the latter being expressly incorporated herein by reference.

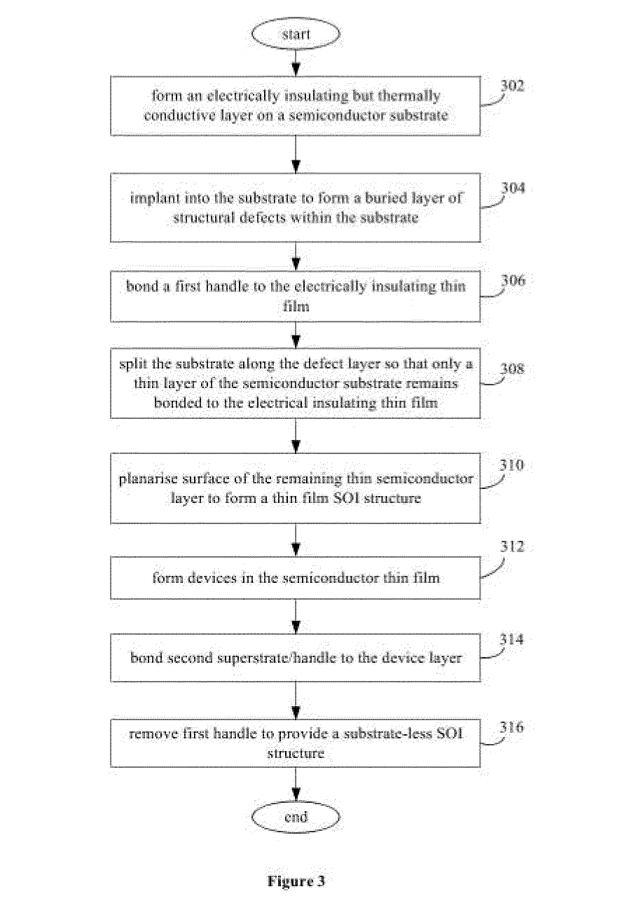

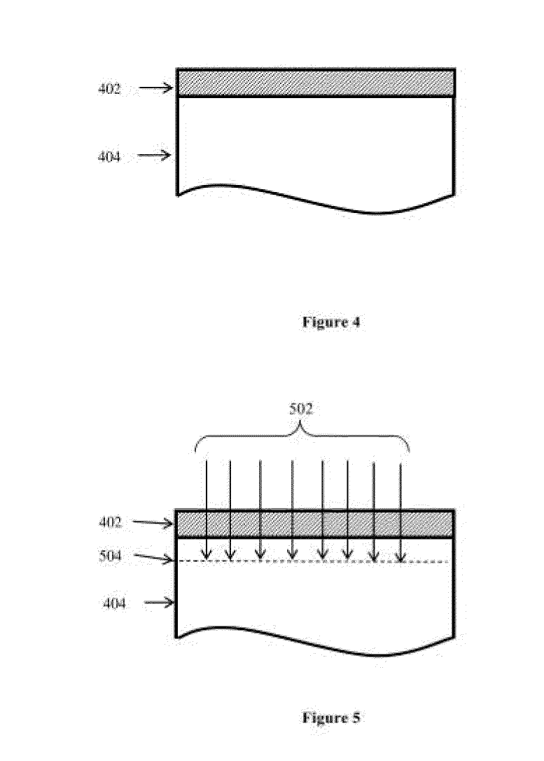

In some embodiments, as shown in FIG. 3, a process for forming a semiconductor-on-insulator (SOI) structure begins at step 302 by forming an electrically insulating but thermally conductive layer 402 on a semiconductor substrate 404, as shown in FIG. 4. The semiconductor substrate is typically an entire semiconductor wafer, and is hereinafter described as such for convenience, but this of course is not necessary. The composition of the semiconductor substrate 404 can be any semiconductor in which semiconductor devices can be made, but in the described embodiments is a device quality (100) silicon wafer having a resistivity >100 Ω-cm.

The composition of the electrically insulating but thermally conductive layer 402 can be any electrical insulator suitable for forming on the semiconductor substrate 404 and compatible with the subsequent processing steps, and the devices formed in the semiconductor substrate 404 and whose thermal conductivity is substantially greater than that of SiO₂ (which is about 1.4 W·m⁻¹·K⁻¹). In the described embodiments, the electrically insulating but thermally conductive layer 402 is an AlN layer having a thickness of about 50-200 nm. In general, the thickness of the AlN layer 402 will be selected to provide sufficient thermal conductance to enable semiconductor devices in the SOI structure to be operated at a desired power. Accordingly, the AlN layer 402 in other embodiments may be thinner or thicker. Typically, the thickness does not exceed about 1 μm, but thicknesses of several microns may be required for some high power applications.

The AlN layer 402 may be grown by any suitable method, including standard methods known to those skilled in the art, such as, for example, reactive sputtering (RS), molecular beam epitaxy (MBE), metallo-organic chemical vapour deposition (MOCVD), or hydride vapour-phase epitaxy (HYPE). AlN has very a high thermal conductivity of 285 W·m⁻¹K⁻¹, substantially greater than silicon (149 W·m⁻¹·K⁻¹) and 3× that of sapphire at 42 W·m⁻¹·K⁻¹. The thermal coefficient of expansion (TCE) of AlN (4.2×10⁻⁶/° C. perpendicular to the c-axis) is substantially closer to the TCE of silicon (2.6×10⁻⁶/° C.) than is sapphire (7×10⁻⁶/° C.), and consequently will result in lower stresses. AlN is a direct bandgap (6.2 eV) material and has good insulating properties (ρ>10¹⁴ Ω-cm) required for fully-depleted CMOS device operation.

Although the SOI structures described herein were developed with high speed and/or high power electronic devices in mind, it will be apparent to those skilled in the art that the process and structures described herein can also be used for other types of devices. Accordingly, the semiconductor devices may include electronic (e.g., micro-electronic or nano-electronic) semiconductor devices and/or photonic devices and/or mechanical devices and/or electro-mechanical devices and the like, or any combination of such devices, which typically have dimensions on a micron scale or smaller.

In some embodiments, the semiconductor substrate 404 is a single-crystal (100)-oriented bulk silicon wafer, although it will be apparent to those skilled in the art that other substrate forms and/or compositions can be used in other embodiments. For example, in some embodiments the substrate 404 is a standard semiconductor-on-insulator substrate in which a thin semiconductor layer is disposed on an electrically insulating layer or substrate.

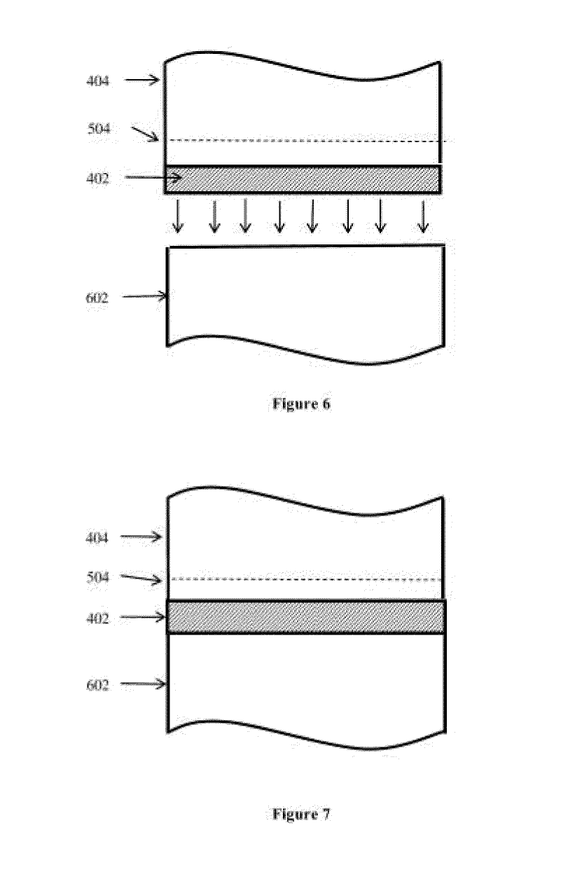

In embodiments where a bulk wafer is used, at step 304 the wafer is ion implanted with a gaseous species 502 through the AlN layer 402 to form a buried implanted layer 504, as shown in FIG. 5. In some embodiments, 150 keV H⁺ ions are implanted to an areal density of about 6×10¹⁶ cm⁻². At step 306, a first handle 602 (which in the described embodiments is a standard silicon wafer, but this need not be the case in other embodiments) is reversibly bonded to the AlN layer 402, as shown in FIGS. 6 and 7, to form a bonded wafer stack. In some embodiments, the first handle 602 is a standard silicon wafer having a polished surface with a surface roughness of <1 nm (RMS).

The bonding between AlN and Si is generally rather poor, but in the context of the described embodiments this is desirable as the bonding is to be reversed later in the process. In any case, the strength of bonding is increased by heating the stack for a short period at a low temperature (e.g., 2 hours at about 120° C.) and then raising the temperature for a longer period (e.g., about 300° C. for 10 hours) to improve the bonding strength. However, it will be apparent to those skilled in the art that other combinations of temperature and time can be readily determined to provide a suitable bond strength that is sufficient to maintain the bonding during processing up until the AlN and Si are separated at step 316, as described below.

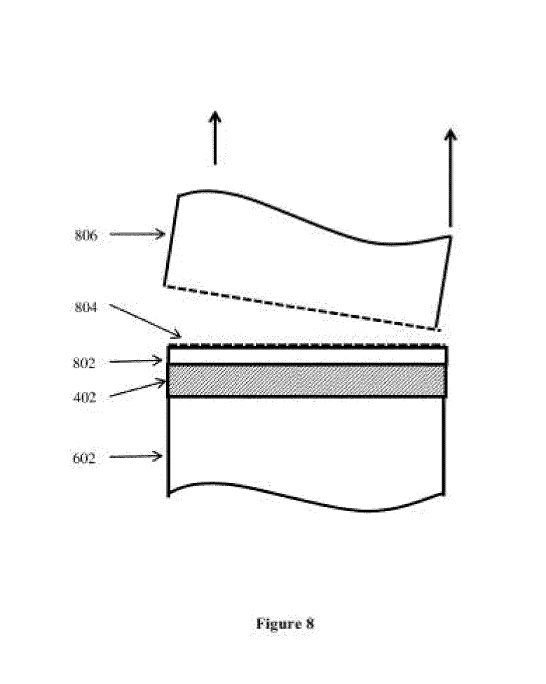

At step 308, the stack is thermally processed to cause the implanted wafer 404 to split into two parts along a buried layer of structural defects corresponding to the implanted layer 504, as shown in FIG. 8, leaving only a relatively thin layer 802 of the (100) silicon attached to the AlN layer 402. Where a hydrogen implant is performed into silicon as described above, in some embodiments this can be achieved by heating the stack to a temperature of about 400-600° C. for about 15 minutes. After removal of the non-bonded portion 806 of the implanted wafer 404 (which can be re-used), the remaining thin layer 802 is annealed at a temperature of about 1100° C. for about 1 hour to anneal any residual damage cause by the implanted hydrogen and to remove hydrogen from the thin layer 802.

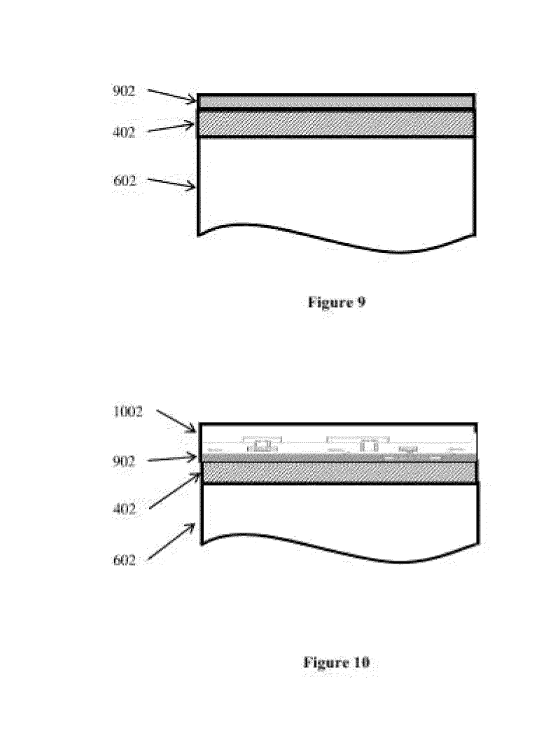

As known by those skilled in the art, ‘ion-cut’ processes such as that described above leave a rough surface 804 on the remaining silicon layer 802. At step 310, this rough surface is then removed, and the silicon layer 802 thinned by a chemical-mechanical polishing (CMP) process, resulting in a smooth, device quality semiconductor thin film 902 on the AlN thin film 402, as shown in FIG. 9. In the described embodiment, the semiconductor thin film 902 is a (100) silicon layer having a thickness of about 110 nm. However, it will be apparent to those skilled in the art that in other embodiments the silicon (or other semiconductor, as the case may be) layer can be essentially any practical thickness, as determined by the energy and species of the implanted ions and by the amount of semiconductor removed by the CMP step.

The structure shown in FIG. 9 has the general form of a standard buried insulator semiconductor-on-insulator (SOI) substrate, but here the insulator material is selected to have a higher thermal conductivity than the semiconductor.

At step 312, devices are formed in the SOI substrate of FIG. 9 using standard processes known to those skilled in the art that are not described further herein. As described above, a variety of different types of devices can be formed, but in the described embodiments the devices include CMOS transistors. As will be apparent to those skilled in the art, these standard processes include forming doped regions in the semiconductor thin film 902 and then forming one or more overlying interconnect layers 1002, as shown in FIG. 10, to provide electrical contacts to some of those regions; for example, by forming and/or depositing and patterning insulating layers such as (in the case of silicon as the semiconductor) silicon oxides and nitrides, silicides, and depositing and patterning metals such as titanium, aluminium, or copper, for example.

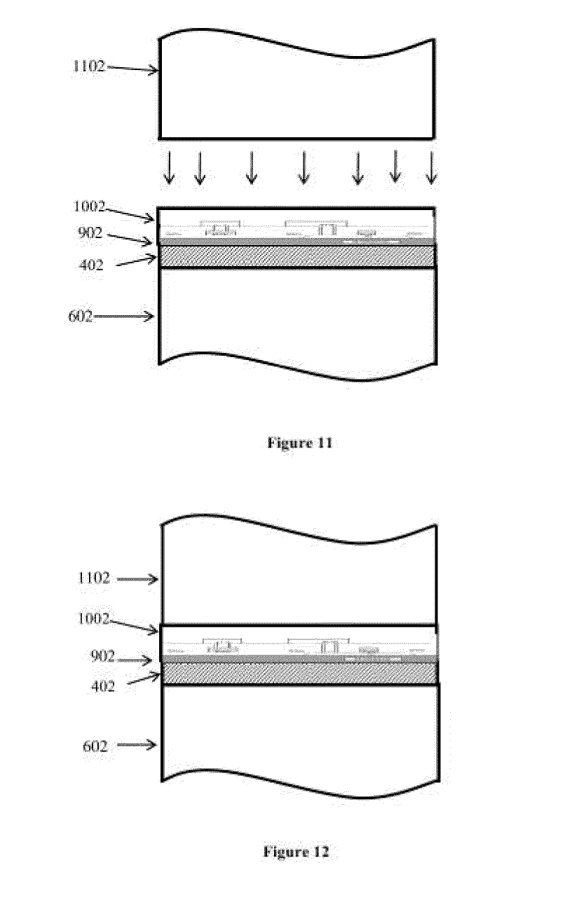

After forming the devices, at step 314 a second handle 1102 is bonded on top of the devices, as shown in FIGS. 11 and 12; that is, the second handle 1102 is bonded to the interconnect layers 1002 formed over the semiconductor thin film 902, which may require planarization of the topmost of the interconnect layers 1002 to provide a flat smooth surface for bonding.

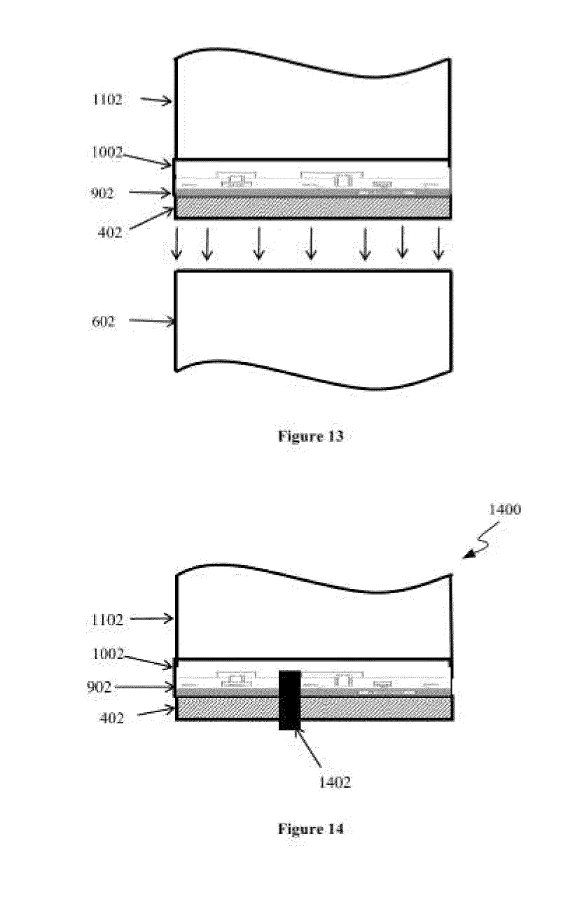

At step 316, the first handle 602 is removed from the AlN layer 104, as shown in FIG. 13, and can be re-used. (Although this may not be the case in other embodiments if the first handle 602 is not reversibly bonded to the AlN layer 104, in which case the first handle 602 may be removed by other means, including destructive means such as cutting, grinding and/or etching, for example.) This exposes the underside of the AlN layer 104, which is very hard, provides an excellent barrier to the environment, and requires no passivation.

In some embodiments, one or more metal bond pads 1402 are formed through the insulating layer 402 and the semiconductor layer 902 using standard patterning and etching methods to form respective electrical connections to the interconnect layer 1002, as shown schematically in FIG. 14. In addition to their electrical function, the bond pads 1402 also act to conduct heat from the AlN layer 104 and the semiconductor layer 902. In embodiments where AlN is used as the electrically insulating material, a positive photoresist developer can be used to selectively etch through the AlN layer, as described in T. J. Anderson, Demonstration of Enhancement Mode AlN/ultrathin AlGaN/GaN HEMTs Using A Selective Wet Etch Approach, MANNTECH Conference, May 17th-20th, 2010, Portland, Oreg., USA. For example, Clariant AZ400K developer at a temperature of 85° C. has been found to etch AlN at a rate of about 4 Å per minute.

Although some methods of producing semiconductor-on-insulator structures have been described above in terms of smart-Cut™ or ion-cut methods to produce the semiconductor thin film 902, other methods may be used in other embodiments. For example, in some embodiments, the ion implantation and substrate splitting steps 304, 108 are omitted and the substrate 404 is thinned using another method, such as grinding and/or chemical etching and polishing, for example. In some embodiments, the substrate 404 is a standard semiconductor-on-insulator substrate in which a thin semiconductor layer is disposed on an electrically insulating layer or substrate that is subsequently removed to leave only the thin semiconductor layer. In yet other embodiments, the semiconductor thin film 902 is formed by growing the semiconductor film 902 directly on the insulating layer 104, which may be single-crystal, poly-crystalline, or amorphous. Thin crystalline silicon layers are currently grown on single-crystal sapphire substrates to produce silicon-on-sapphire wafers, but the lattice mismatch between the silicon and the sapphire causes the formation of twin crystal defects to form in the silicon layer during growth. As the lattice spacing of single-crystal AlN is a closer match to silicon than sapphire, the quality of single-crystal silicon grown on single-crystal AlN can be better than that of silicon grown on sapphire. Accordingly, in some embodiments the insulating layer 104 is a single-crystal AlN layer grown on a (100) (or, in some embodiments, (111)) silicon substrate, and the semiconductor thin film 902 is a (100) silicon layer grown on the AlN layer by a standard epitaxial growth method such as MBE or MOCVD or HVPE or reactive sputtering.

As will be appreciated by those skilled in the art, prior to its removal, the first handle 602 (which may be a silicon wafer) is analogous to the underlying bulk semiconductor in a standard buried-insulator SOI wafer, and in this context is generally referred to in the art as the substrate. Accordingly, the final SOI structure 1400 shown in FIG. 14 may be referred to as a ‘substrate-less’ SOI structure.

As described above, despite the reduction of parasitic capacitance in prior art SOI wafers due to the presence of a buried oxide layer, the inventor has determined that the remaining parasitic capacitance due to the presence of the bulk semiconductor below the buried oxide layer continues to limit the performance of devices formed in the such wafers. Consequently, the ‘substrate-less’ SOI structures described herein, such as the SOI structure 1400 shown in FIG. 14, provide further reductions in parasitic capacitance, and hence improved high frequency device performance. The physical separation between the semiconductor thin film 902 and the second handle 1102 (due to the presence of the interconnect layers 1002 therebetween) is so large that the presence of the second handle 1102 substantially does not introduce any further parasitic capacitance. The potential self-heating issues potentially aggravated by the absence of a bulk substrate as a heat sink can be addressed or alleviated by selecting the insulating layer 402 under the devices to have a thermal conductivity greater than that of SiO₂ or even of the semiconductor layer 902 in which the devices are formed. This facilitates the conduction of heat from the devices through the thin film insulator to heat sinks such as metallic bumps, wire bonds, or other thermally conductive components. In practice, there needs to be a balance between increasing the thickness of the thin film insulator to increase the in-plane conduction through the film on the one hand, and on the other hand reducing the thickness to reduce parasitic electrical effects. Typically, a thin film insulator thickness in the range from 50 nm to at least one micron or several microns provides a good balance between these competing requirements.

The semiconductor-on-insulator (SOI) structures described herein thus enable the production of relatively low-cost, high performance devices such as fully-depleted or partially depleted complementary metal oxide silicon (CMOS) circuits (including RF switches for mobile telephones and similar devices) for high frequency and power applications with reduced self-heating effects.

Many modifications will be apparent to those skilled in the art without departing from the scope of the present invention.

1. A semiconductor-on-insulator structure, including a semiconductor thin film having electronic devices formed therein, the semiconductor thin film being disposed on a first face of an electrically insulating thin film; wherein to reduce parasitic capacitance, there is no bulk substrate attached to a second face of the electrically insulating thin film opposite to the first face, and to provide a path for heat flow from the devices, the thermal conductivity of the electrically insulating thin film is substantially greater than 1.4 W·m⁻¹·K⁻¹.

2. The structure of claim 1, wherein there is no other layer with a thermal conductivity comparable to that of the electrically insulating thin film attached to the second face of the electrically insulating thin film.

3. The structure of claim 1, wherein there is substantially no other layer attached to the second face of the electrically insulating thin film.

4. The structure of claim 1, wherein the electrically insulating thin film is a crystalline thin film having an epitaxial relationship with the semiconductor thin film.

5. The structure of claim 1, wherein the thermal conductivity of the electrically insulating thin film is at least 14 W·m⁻¹·K⁻¹.

6. The structure of claim 1, wherein the thermal conductivity of the electrically insulating thin film is at least about 100 W·m⁻¹K⁻¹.

7. The structure of claim 1, wherein the thermal conductivity of the electrically insulating thin film is at least nearly equal to that of the semiconductor thin film.

8. The structure of claim 1, wherein the thermal conductivity of the electrically insulating thin film is greater than that of the semiconductor thin film.

9. The structure of claim 1, including at least one interconnect layer disposed on the semiconductor thin film, the at least one interconnect layer including electrical contacts to the devices in the semiconductor thin film.

10. The structure of claim 9, including one or more bond pads extending from the at least one interconnect layer through the semiconductor thin film and the electrically insulating thin film to provide electrical contacts to the devices and to provide a thermal path for heat flow from the devices and the electrically insulating thin film.

11. The structure of claim 9, including a support attached to the interconnect layer to provide mechanical support for the semiconductor thin film and the electrically insulating thin film.

12. The structure of claim 1, wherein the devices include fully-depleted and/or partially depleted CMOS devices.

13. The structure of claim 1, wherein the devices include RF switches.

14. The structure of claim 1, wherein the electrically insulating thin film is an AlN thin film.

15. The structure of claim 1, wherein the semiconductor thin film is a silicon thin film.

16. A process for producing a semiconductor-on-insulator structure, including:
forming a semiconductor thin film disposed on a first face of an electrically insulating thin film;
forming electronic devices in the semiconductor thin film;
wherein to reduce parasitic capacitance, there is no bulk substrate attached to a second face of the electrically insulating thin film opposite to the first face, and to provide a path for heat flow from the devices, the thermal conductivity of the electrically insulating thin film is substantially greater than 1.4 W·m⁻¹·K⁻¹.

17. The process of claim 16, wherein there is no other layer with a thermal conductivity comparable to that of the electrically insulating thin film attached to the second face of the electrically insulating thin film.

18. The process of claim 16, wherein there is substantially no other layer attached to the second face of the electrically insulating thin film.

19. The process of claim 16, wherein the electrically insulating thin film is a crystalline thin film having an epitaxial relationship with the semiconductor thin film.

20. The process of claim 16, wherein the thermal conductivity of the electrically insulating thin film is at least 14 W·m⁻¹K⁻¹.

21. The process of claim 16, wherein the thermal conductivity of the electrically insulating thin film is at least about 100 W·m⁻¹K⁻¹.

22. The process of claim 16, wherein the thermal conductivity of the electrically insulating thin film is at least nearly equal to that of the semiconductor thin film.

23. The process of claim 16, wherein the thermal conductivity of the electrically insulating thin film is greater than that of the thin film semiconductor.

24. The process of claim 16, wherein the step of forming the semiconductor thin film disposed on the first face of the electrically insulating thin film includes growing the semiconductor thin film on the electrically insulating thin film.

25. The process of claim 16, wherein the step of forming the semiconductor thin film disposed on the first face of the electrically insulating thin film includes:
forming the electrically insulating thin film on a semiconductor substrate;
bonding a first handle layer to the electrically insulating thin film;
removing most of the semiconductor substrate to provide the semiconductor thin film bonded to the electrically insulating thin film; and
removing the first handle layer from the electrically insulating thin film.

26. The process of claim 25, wherein the semiconductor substrate is a buried insulator semiconductor-on-insulator substrate including a buried insulating layer disposed between the semiconductor thin film and a bulk semiconductor substrate.

27. The process of claim 25, including forming at least one interconnect layer disposed on the semiconductor thin film, the at least one interconnect layer including electrical contacts to the electronic devices formed in the semiconductor thin film, and the process includes bonding a second handle layer to the at least one interconnect layer prior to removing the first handle layer.

28. The process of claim 27, including planarising a surface of the at least one interconnect layer prior to bonding to the second handle layer.

29. The process of claim 27, including forming one or more bond pads extending from the at least one interconnect layer through the semiconductor thin film and the electrically insulating thin film to provide electrical contacts to the electronic devices and to provide a thermal path for heat flow from the devices and the electrically insulating thin film.

30. The process of claim 25, wherein the step of forming the semiconductor thin film disposed on the first face of the electrically insulating thin film includes:
forming the electrically insulating thin film on a semiconductor substrate;
directing an energetic beam of particles into the semiconductor substrate to form a buried implanted layer within the semiconductor substrate;
bonding a first handle layer to the electrically insulating thin film;
splitting the semiconductor substrate along a layer of structural defects corresponding to the buried implanted layer to leave a relatively thin layer of the semiconductor substrate bonded to the electrically insulating thin film;
planarising the relatively thin layer of the semiconductor substrate to provide the semiconductor thin film disposed on the first face of the electrically insulating thin film; and
removing the first handle layer from the electrically insulating thin film.

31. The process of claim 30, wherein the energetic beam of particles is directed through the electrically insulating layer into the semiconductor substrate.

32. The process of claim 16, wherein the electronic devices include fully-depleted and/or partially depleted CMOS devices.

33. The process of claim 16, wherein the devices include RF switches.

34. The process of claim 16, wherein the electrically insulating thin film is an AlN thin film.

35. The process of claim 16, wherein the semiconductor thin film is a silicon thin film.

36. The process of claim 16, wherein the bonding of the first handle layer to the electrically insulating thin film is reversible, and the removal of the first handle layer from the electrically insulating thin film is achieved by applying a force sufficient to break bonds between the first handle layer and the electrically insulating thin film.
